(19) United States
(12) Patent Application Publication
(10) Pub. No.: US 2024/0387437 A1
(43) Pub. Date: Nov. 21, 2024

(54) SENSOR DEVICE AND METHOD FOR MANUFACTURING SENSOR DEVICE

(71) Applicants: Soichiro SUZU, Tokyo (JP); Satoshi KURIBAYASHI, Tokyo (JP)

(72) Inventors: Soichiro SUZU, Tokyo (JP); Satoshi KURIBAYASHI, Tokyo (JP)

(73) Assignee: MITSUMI ELECTRIC CO., LTD., Tokyo (JP)

(21) Appl. No.: 18/653,287

(22) Filed: May 2, 2024

(30) Foreign Application Priority Data
May 17, 2023 (JP) 2023-081852

(51) Int. Cl. H01L 23/00

(52) U.S. Cl. CPC H01L 24/29; H01L 24/48; H01L 24/83; H01L 2224/2956; H01L 2224/29599; H01L 2224/48227; H01L 2924/146

(57) ABSTRACT

A sensor device includes a semiconductor sensor element and a substrate on which the semiconductor sensor element is mounted. The substrate includes a sensor-element mounted portion at which the semiconductor sensor element is mounted, and includes a first resist portion that surrounds the sensor-element mounted portion. The substrate includes a first region adjacent to the first resist portion and being covered with a resin layer, and includes a second resist portion that surrounds the first resist portion, the first region being interposed between the first resist portion and the second resist portion. The substrate includes at least one third resist portion extending from the first resist portion toward the second resist portion.

### CROSS-REFERENCE TO RELATED APPLICATIONS

This application claims priority under 35 U.S. C. § 119 to Japanese Patent Application No. 2023-081852, filed May 17, 2023, the contents of which are incorporated herein by reference in its entirety.

### BACKGROUND

### 1. Technical Field

The present disclosure relates to a sensor device and a method for manufacturing the sensor device.

### 2. Description of the Related Art

Patent Document 1 discloses a sensor device. The sensor device includes a substrate with a base, a semiconductor sensor element mounted on the substrate, wire bonding pads that are wire bonded to the semiconductor sensor element, a resist film with which a portion of the base is covered, and a resin layer with which an exposed base is covered.

### Related-Art Document

### Patent Document

Patent Document 1: Japanese Unexamined Patent Application Publication No. 2012-73233

### SUMMARY

A sensor device in the present disclosure includes a semiconductor sensor element and a substrate on which the semiconductor sensor element is mounted. The substrate includes a sensor-element mounted portion at which the semiconductor sensor element is mounted, a first resist portion that surrounds the sensor-element mounted portion, and a first region adjacent to the first resist portion, and being covered with a resin layer. The sensor device includes a second resist portion that surrounds the first resist portion, the first region being interposed between the first resist portion and the second resist portion. The sensor device includes at least one third resist portion extending from the first resist portion toward the second resist portion.

A method for manufacturing a sensor device by mounting a semiconductor sensor element at a sensor-element mounted portion in a substrate includes forming a first resist portion to surround the sensor-element mounted portion; forming a second resist portion to surround the first resist portion such that a first region is interposed between the first resist portion and the second resist portion; forming at least one third resist portion that extends from the first resist portion toward the second resist portion; disposing a resin infusion unit above the third resist portion and infusing a resin from the resin infusion unit; and forming a resin layer that covers the first region as a result of infusing the resin.

### BRIEF DESCRIPTION OF THE DRAWINGS

FIG. 1 is a plan view of a substrate in a sensor device before mounting a semiconductor sensor element according to a first embodiment.

FIG. 2 is a plan view of the sensor device according to the first embodiment.

FIG. 3 is an enlarged plan view of a third resist portion.

FIG. 4 is a sectional view of the sensor device taken along the line IV-IV in FIG. 2.

FIG. 5 is a sectional view of a sensor device in related art.

FIG. 6 is a flowchart showing a method for manufacturing the sensor device.

FIG. 7 is a plan view of the sensor device according to a second embodiment.

FIG. 8 is a plan view of the sensor device according to a third embodiment.

### DETAILED DESCRIPTION

The inventors of this application have recognized the following information in the related art. In a sensor device, after a resin is infused onto a substrate, the resin may not sufficiently be spread. In view of the situation recognized by the inventors, an object of the present disclosure is to provide a sensor device and a method for manufacturing the sensor device that is capable of remedying insufficient spreading of the resin.

The sensor device and the method for manufacturing the sensor device will be described below with reference to the drawings. In the specification and drawings, the substantially the same components are denoted by the same numbers and duplicate description may be omitted.

### Sensor Device According to First Embodiment

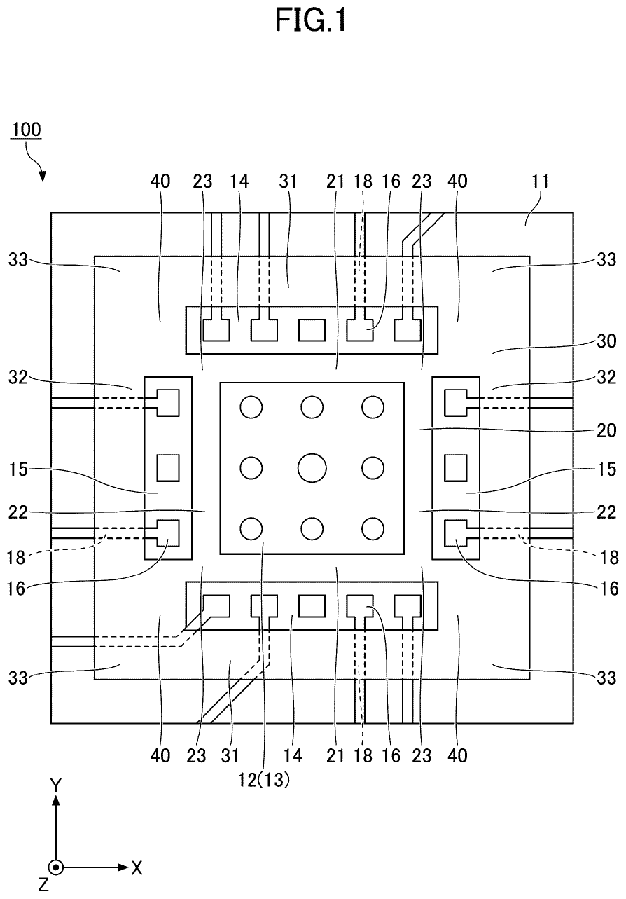

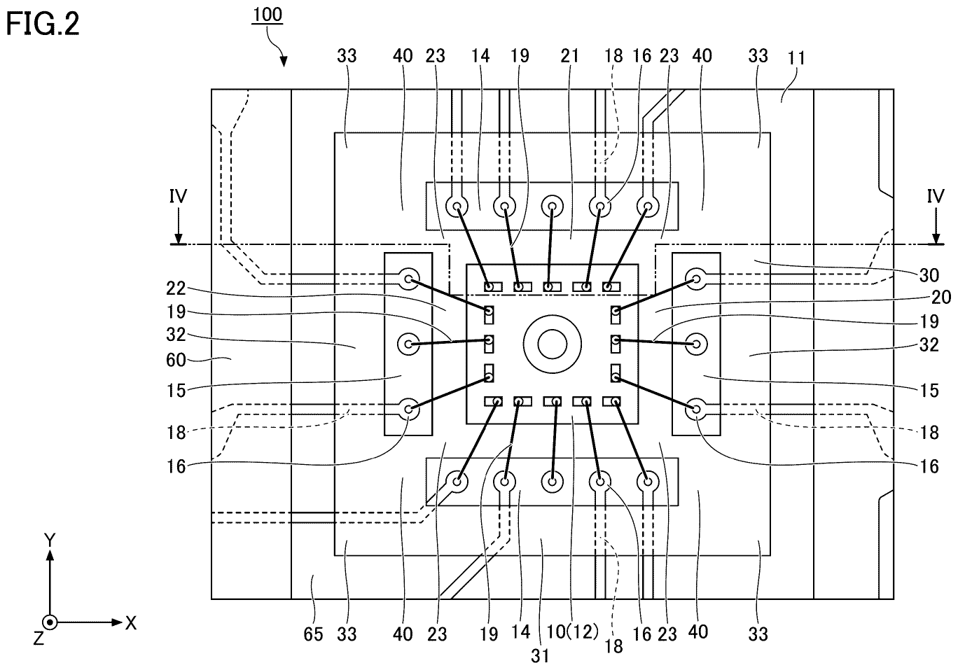

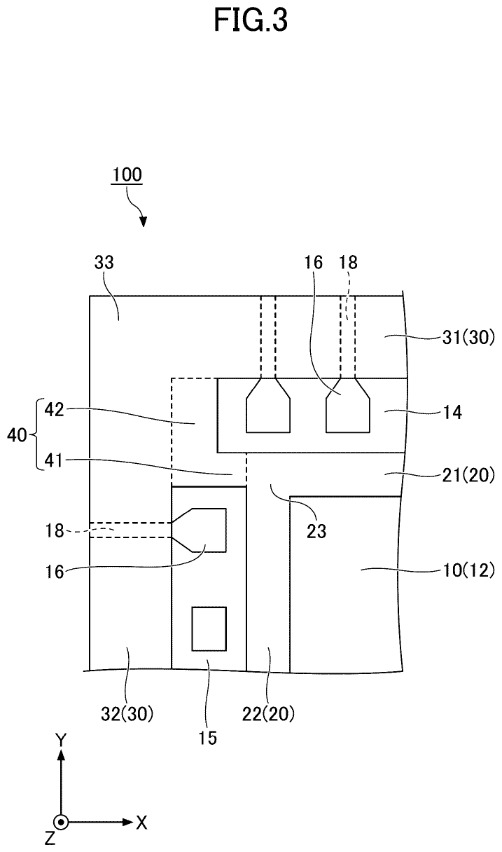

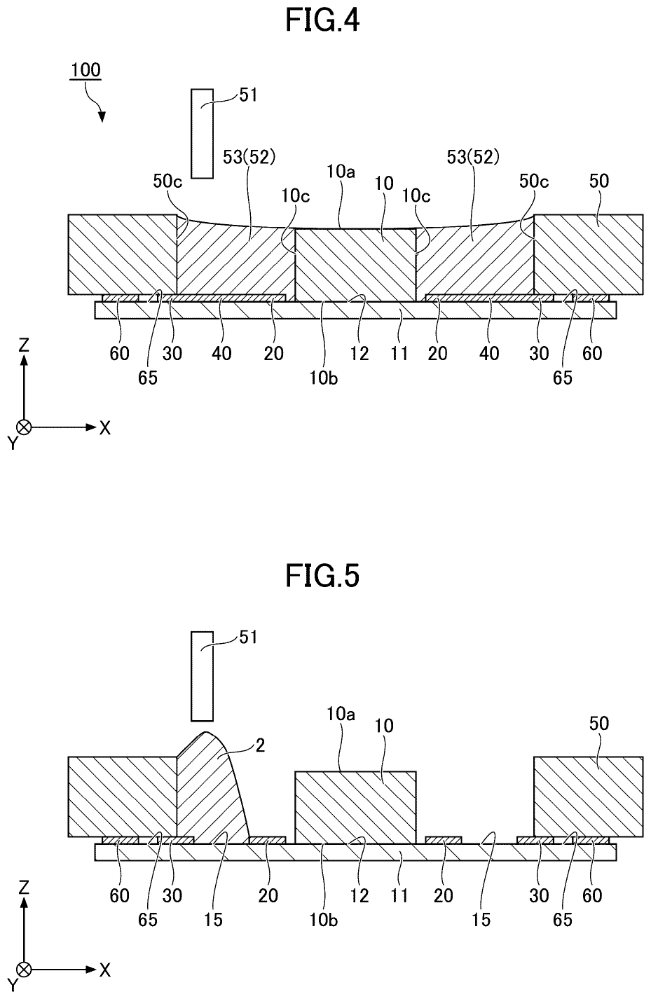

Hereinafter, a sensor device 100 according to a first embodiment will be described with reference to FIGS. 1 to 3. FIG. 1 is a plan view of a substrate 11 in the sensor device 100 before mounting a semiconductor sensor element 10 according to the first embodiment. FIG. 2 is a plan view of the sensor device 100 according to the first embodiment. FIG. 3 is an enlarged plan view of a third resist portion 40. FIG. 4 is a cross-sectional view of the sensor device 100 taken along line IV-IV in FIG. 2. In FIGS. 1 to 3, an X axis, a Y axis, and a Z axis that are orthogonal to one another are shown for reference. If necessary, the X axis, the Y axis, and the Z axis are shown in other drawings.

As shown in FIGS. 1 and 2, the sensor device 100 includes the substrate 11 with a sensor-element mounted portion 12. As shown in FIGS. 2 to 4, the sensor device 100 includes a semiconductor sensor element 10 that is mounted on the sensor-element mounted portion 12. The sensor device 100 includes the semiconductor sensor element 10 and the substrate 11 on which the semiconductor sensor element 10 is mounted. The substrate 11 includes the sensor-element mounted portion 12, a first resist portion 20, first regions 14 and 15, second resist portions 30, and third resist portions 40. The first region 14 and 15 are covered with a resin layer 53.

### [Sensor-Element Mounted Portion]

As shown in FIG. 1, the sensor-element mounted portion 12 includes a base 13 that is exposed at a surface of the substrate 11. The base 13 exposed at the surface means that the base 13 is not covered with, for example, a resist film. The sensor-element mounted portion 12 with the base 13 is covered with the semiconductor sensor element 10 and an adhesive resin.

The sensor-element mounted portion 12 is formed to have a rectangular shape in a plan view. The sensor-element mounted portion 12 has substantially the same size as the semiconductor sensor element 10 in the plan view.

### [First Resist Portion]

The first resist portion 20 is formed on the substrate 11. The first resist portion 20 is formed so as to surround the sensor-element mounted portion 12 in the plan view. The first resist portion 20 has a rectangular frame shape in the plan view. The first resist portion 20 includes a pair of first pieces 21 and a pair of second pieces 22.

The first pieces 21 making the pair face each other in the Y-axis direction, and extend in the X-axis direction. The second pieces 22 making the pair face each other in the X-axis direction, and extend in the Y-axis direction. The Y-axis direction is an example of a first direction, and the X-axis direction is an example of a second direction. The first resist portion 20 has a predetermined thickness in the Z-axis direction. In the example shown in the figures, the first direction and the second direction are orthogonal to each other, but the present disclosure is not limited to the above example. The first direction and the second direction may intersect each other.

In a plan view, the sensor-element mounted portion 12 is formed inside the first resist portion 20. The first resist portion 20 has a function of preventing the adhesive resin that is infused onto the sensor-element mounted portion 12, from flowing out. The adhesive resin for bonding the semiconductor sensor element 10 is infused onto the sensor-element mounted portion 12. The adhesive resin at the sensor-element mounted portion 12 is blocked by the first resist portion 20.

### [First Region]

The first regions 14 and 15 that are exposed at the surface of the substrate 11 are formed on the substrate 11. The first regions 14 and 15 are not covered with, for example, the resist film. The first regions 14 and 15 are each covered with a resin 52 as described below (see FIG. 4). The first regions 14 and 15 are adjacent to the first resist portion 20 in a plan view. Two first regions 14 extend in the X-axis direction perpendicular to the Y-axis direction. Two first regions 15 extend in Y-axis direction perpendicular to the X-axis direction.

Each first region 14 is formed adjacent to the first piece 21. The first region 14 is disposed on a side opposite a first piece 21 side of the sensor-element mounted portion 12. In other words, the first piece 21 is formed between the sensor-element mounted portion 12 and the first region 14 in the Y-axis direction. The first region 14 has a predetermined width in the Y-axis direction. The first region 14 has a predetermined length in the X-axis direction.

Each first region 15 is formed adjacent to the second piece 22. The first region 15 is disposed on a side opposite a second piece 22 side of the sensor-element mounted portion 12. In other words, the second piece 22 is formed between the sensor-element mounted portion 12 and the first region 15 in the X-axis direction. The first region 15 has a predetermined width in the X-axis direction. The first region 15 has a predetermined length in the Y-axis direction.

### [Wire Bonding Pad]

The sensor device 100 includes wire bonding pads 16. The wire bonding pads 16 are each formed in a corresponding region among the first regions 14 and 15. The given wire bonding pads 16 that are arranged in the X-axis direction are formed in each first region 14. The given wire bonding pads 16 that are arranged in the Y-axis direction are formed in each first region 15.

Each wire bonding pad 16 is connected to a wiring 18. The wiring 18 is formed on the surface of the substrate 11. The wiring 18 extends in a direction away from the semiconductor sensor element 10 and the sensor-element mounted portion 12, in a plan view.

### [Wire Bonding]

As shown in FIG. 2, the semiconductor sensor element 10 and each wire bonding pad 16 are wire bonded to each other. The sensor device 100 includes bonding wires 19. Each bonding wire 19 connects the semiconductor sensor element 10 to the wire bonding pad 16.

### [Second Resist Portion]

The second resist portion 30 is formed on the substrate 11. In a plan view, the second resist portion 30 is formed to surround the first resist portion 20 such that the first regions 14 and 15 are interposed between the first resist portion 20 and the second resist portion 30. The second resist portion 30 has a rectangular frame shape in the plan view. The second resist portion 30 includes a pair of first pieces 31 and a pair of second pieces 32.

First pieces 31 making the pair face each other in the Y-axis direction, and extend in the X-axis direction. Second pieces 32 making the pair face each other in the X-axis direction, and extend in the Y-axis direction. The second resist portion 30 has a predetermined thickness in the Z-axis direction. The thickness of the second resist portion 30 is the same as the thickness of the first resist portion 20. The expression “the same” covers “substantially the same.”

### [Third Resist Portion]

The third resist portion 40 is formed on the substrate 11. The third resist portion 40 extends from the first resist portion 20 toward the second resist portion 30 in a plan view. A case where the third resist portion 40 extends from the first resist portion 20 toward the second resist portion 30 covers a case where the third resist portion 40 extends from the second resist portion 30 toward the first resist portion 20.

The third resist portion 40 connects the first resist portion 20 and the second resist portion 30. As shown in FIG. 3, each end of the third resist portion 40 that is closer to the first resist portion 20 is connected to a corner 23 where the first piece 21 and the second piece 22 intersect. Each end of the third resist portion 40 that is closer to the second resist portion 30 is connected to a corner 33 where the first piece 31 and the second piece 32 intersect.

Each third resist portion 40 includes a first portion 41 and a second portion 42. The third resist portion 40 is formed to have an L shape in a plan view. The first portion 41 is connected to the corner 23 where the first piece 21 and the second piece 22 intersect. The first portion 41 extends in the X-axis direction. The first portion 41 extends in a longitudinal direction of the first piece 21. The first portion 41 may be connected to the second piece 32. The first portion 41 is formed between the first region 14 and the first region 15 in the Y-axis direction. The first portion 41 is formed between the first piece 21 and the second piece 32 in the X-axis direction.

The second portion 42 is connected to the first portion 41, and extends in the Y-axis direction. The second portion 42 extends along a longitudinal direction of the second piece 32. The second portion 42 is connected to a corner 33 where the first piece 31 and the second piece 32 intersect. The second portion 42 is formed between the first region 14 and the second piece 32 in the X-axis direction. The second portion 42 is disposed between the first piece 31 and the first region 15 in the Y-axis direction. The second portion 42 is formed between the first piece 31 and the first portion 41 in the Y-axis direction.

The third resist portion 40 is arranged to correspond to all portions of the corner 23 of the first resist portion 20 having a rectangular shape. The thickness of the third resist portion 40 in the Z-axis direction may be the same as the thickness of the first resist portion 20. The thickness of the third resist portion 40 in the Z-axis direction may be the same as the thickness of the second resist portion 30.

### [Second Region]

As shown in FIGS. 2 and 4, the substrate 11 has a second region 65 that is exposed at the surface of the substrate 11. The second region 65 is formed so as to surround the second resist portion 30 in a plan view. The second region 65 is formed to have a rectangular frame shape.

### [Fourth Resist Portion]

The fourth resist portion 60 is formed on the substrate 11. The fourth resist portion 60 may be formed so as to surround the second resist portion 30 such that the second region 65 is interposed between the fourth resist portion 60 and the second resist portion 30 in a plan view. The fourth resist portion 60 may be formed to have a rectangular shape in the plan view. The second region 65 is disposed between the second resist portion 30 and the fourth resist portion 60 in the plan view.

### [Package]

As shown in FIG. 4, the sensor device 100 includes a package 50. The package 50 is bonded to the second resist portion 30 and the fourth resist portion 60, for example, with an adhesive resin. The package 50 is disposed so as to overlap the outer periphery of the second resist portion 30 in a plan view. The package 50 may be bonded to the second region 65 exposed at the surface of the substrate 11. The package 50 may be a housing of the sensor device 100. For example, the package 50 can be bonded to the substrate 11 with an epoxy resin as an adhesive.

### [Semiconductor Sensor Element]

The semiconductor sensor element 10 may be, for example, a semiconductor-pressure sensor element. The semiconductor sensor element 10 is not limited to the semiconductor-pressure sensor element. The semiconductor sensor element 10 may include, for example, a temperature sensor, a humidity sensor, or the other sensor elements. The semiconductor sensor element 10 may include a micro-electromechanical systems (MEMS) sensor chip and a glass substrate.

As described above, the semiconductor sensor element 10 is mounted on the sensor-element mounted portion 12. The semiconductor sensor element 10 is bonded to the sensor-element mounted portion 12 of the substrate 11, with the adhesive resin. The semiconductor sensor element 10 has a first surface 10a and a second surface 10b that are opposed to each other. The first surface 10a is disposed on a side opposite a substrate 11-side. The first surface 10a is not covered with a resin 52 described below. The first surface 10a is an example of an exposed surface that is a surface exposed to the outside of the sensor device 100. The entire first surface 10a may be exposed to the outside, or a portion of the first surface 10a may be exposed to the outside.

The second surface 10b includes a surface facing the substrate 11 in the Z-axis direction. The substrate 11 is bonded to the second surface 10b. For example, the semiconductor sensor element 10 can be bonded to the substrate 11 with a die bond resin, such as a silicon resin, that is used as an adhesive.

### [Resin]

The sensor device 100 includes a resin layer 53 containing the resin 52. The resin layer 53 is formed by applying the resin 52. The resin layer 53 is disposed to fill a space between the package 50 and the semiconductor sensor element 10. The resin layer 53 is formed to cover the first resist portion 20, the first regions 14 and 15, the second resist portion 30, and the third resist portion 40 as shown in FIG. 2.

When the resin 52 is infused onto the substrate 11, the resin 52 is infused using, for example, a needle 51. The needle 51 is an example of a resin infusion unit. The resin infusion unit includes one or more nozzles for discharging the resin. A resin infusion device for infusing the resin 52 includes the needle 51. The needle 51 infuses the resin 52 in a state of being disposed above the third resist portion 40, for example. The needle 51 may be disposed above the first portion 41, or may be disposed above the second portion 42.

The resin 52 that flows out from the needle 51 falls and is infused onto the third resist portion 40. For example, the infused resin 52 flows from the package 50 toward the semiconductor sensor element 10, so as to be on the third resist portion 40. A portion of the resin 52 flows in a direction approaching the first resist portion 20 from the second resist portion 30. A portion of the resin 52 may flow in any other direction(s).

The resin 52 may be infused onto the second portion 42, for example. The resin 52 infused onto the second portion 42 flows from the second portion 42 onto the first portion 41, and then reaches a side surface 10c of the semiconductor sensor element 10.

A portion of the resin 52 infused onto the third resist portion 40 flows and spreads on the second resist portion 30. The resin 52 is in contact with a side surface 50c of the package 50. A part of the resin 52 injected onto the third resist portion 40 flows onto the first resist portion 20. A portion of the resin 52 flows and spreads on the first resist portion 20.

A portion of the resin 52 on the third resist portion 40 flows onto the first regions 14 and 15. A portion of the resin 52 on the second resist portion 30 flows onto the first regions 14 and 15. A portion of the resin 52 on the first resist portion 20 flows onto the first regions 14 and 15.

The first resist portion 20, the second resist portion 30, the third resist portion 40, and the first regions 14 and 15 are covered and protected with the resin 52. The wire bonding pads 16 formed in the first regions 14 and 15 are covered and protected with the resin 52. The resin layer 53 covers the first resist portion 20, the second resist portion 30, the third resist portion 40, and the first regions 14 and 15. The resin layer 53 covers the wire bonding pads 16 and a portion of each bonding wire 19.

### [Problem in Related Art]

A problem in the related art will be described hereinafter. FIG. 5 is a cross-sectional view of a sensor device 1 in the related art. A sensor device 1 in the related art includes a semiconductor sensor element 10, a substrate 11, a first resist portion 20, a second resist portion 30, a fourth resist portion 60, and a package 50. The sensor device 1 in the related art does not include a third resist portion 40. In the sensor device 1, the first region 15 has a greater length in the Y-axis direction and is connected to a first region 14.

In the sensor device 1, a resin 2 flowing out from the needle 51 is supplied onto the second resist portion 30 and the first region 15. In this case, the resin 2 on the first region 15 may be blocked by the first resist portion 20. The first resist portion 20 serves as a step with respect to a base in the first region 15 where a resist film is not formed. The resin 2 in the first region 15 is caught by the first resist portion 20 serving as the step, and as a result, the resin 2 is unlikely to flow onto the first resist portion 20. For this reason, in the related art, there are some cases where the resin 2 is not spread sufficiently. If repairing is performed to address such an issue of the resin 2, this might result in reduced yield efficiency. In addition, the semiconductor sensor element 10 might be damaged during repairing.

If there is a larger region of the sensor device that is not protected with the resin 2, the resulting sensor device has reduced reliability, and thus the sensor device could not be used as a product. Further, if the first resist portion 20 is removed to eliminate the step, a problem might occur in which the resin for bonding the semiconductor sensor element 10 is spread over a wide range when mounting the semiconductor sensor element 10.

### Operation and Effect of Sensor Device According to First Embodiment

The sensor device 100 according to the first embodiment includes the semiconductor sensor element 10 having the first surface 10a that is exposed externally, and includes the substrate 11 having a sensor-element mounted portion 12 at which the semiconductor sensor element 10 is mounted. The substrate 11 includes the first resist portion 20 formed to surround the sensor-element mounted portion 12 in a plan view, first regions 14 and 15 each of which is adjacent to the first resist portion 20 in the plan view, the second resist portion 30 formed to surround the first resist portion 20 such that the first regions 14 and 15 are interposed between the first resist portion 20 and the second resist portion 30 in the plan view, and the third resist portion 40 extending from the first resist portion 20 toward the second resist portion 30 in the plan view. The first regions 14 and 15 are covered with the resin layer 53 containing the resin 52.

In such a sensor device 100, the resin 52 can be infused onto the third resist portion 40 during manufacturing, and as a result, the resin 52 can be spread along the third resist portion 40. The resin 52 on the third resist portion 40 flows onto the first regions 14 and 15. The resin 52 on the third resist portion 40 flows onto the second resist portion 30 and the third resist portion 40. The resin 52 on the second resist portion 30 and the third resist portion 40 flows onto the first regions 14 and 15. With this approach, in the sensor device 100, the resin 52 can be sufficiently spread. In the sensor device 100, insufficient spreading of the resin can be remedied.

In the sensor device 100, the resin 52 can be sufficiently spread, and thus a yield in manufacturing the sensor device 100 can be improved. In the sensor device 100, a frequency of the repairing of the resin 52 can be reduced. In the sensor device 100, the possibility of damaging the semiconductor sensor element 10 is reduced when repairing the resin 52.

In the sensor device 100, the resin 52 is sufficiently spread, and thus the first resist portion 20, the second resist portion 30, the first regions 14 and 15, the third resist portions 40, the wire bonding pads 16, and the bonding wires 19 can be covered with the resin 52. Therefore, the reliability of the sensor device 100 can be improved.

In the sensor device 100, each third resist portion 40 is formed to connect the first resist portion 20 and the second resist portion 30. In this case, during manufacturing of the sensor device 100, the resin 52 on the third resist portion 40 easily flows onto the first resist portion 20. Similarly, the resin 52 on the third resist portion 40 easily flows onto the second resist portion 30. Even if the resin 52 does not flow from the first regions 14 and 15 onto the first resist portion 20, the resin 52 can flow from the third resist portion 40 onto the first resist portion 20.

In the sensor device 100, the first resist portion 20 having a rectangular shape in a plan view includes two first pieces 21 that face each other in the Y-axis direction as a first direction, and that extend in the X-axis direction as a second direction. Also, the first resist portion 20 includes two second pieces 22 that face each other in the X-axis direction and that extend in the Y-axis direction. Each third resist portion 40 is connected to the corner 23 where the first piece 21 and the second piece 22 intersect. In the sensor device 100 having such a configuration, the resin 52 on the third resist portion 40 can flow from the corner 23 of the first resist portion 20 onto the first resist portion 20, during manufacturing of the sensor device 100.

In the sensor device 100, each third resist portion 40 includes the first portion 41 that extends from the corner 23 in the X-axis direction and that is connected to the second resist portion 30. Also, each third resist portion 40 includes the second portion 42 that is connected to the first portion 41 and that extends in the Y-axis direction. In the sensor device 100 having such a configuration, a resin on the first portion 41 can flow in the X-axis direction during manufacturing of the sensor device. In the sensor device 100, a resin on the second portion 42 can flow in the Y-axis direction. In the sensor device 100, the resin 52 can be sufficiently spread.

### [Method for Manufacturing Sensor Device]

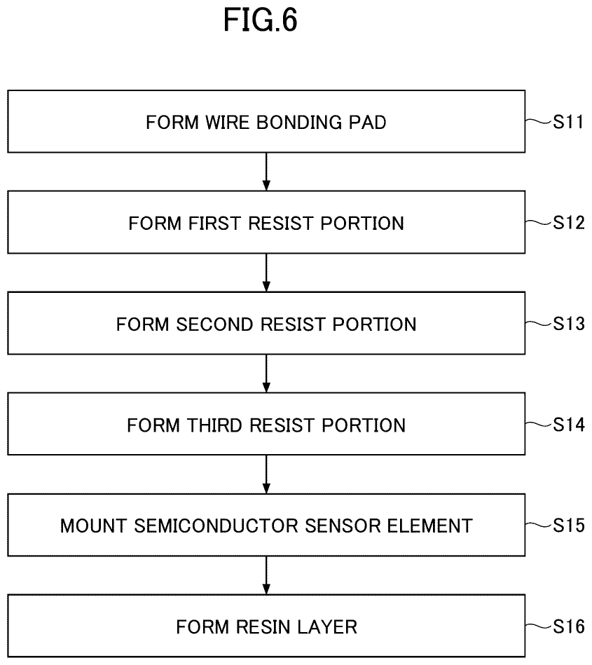

Hereinafter, an example of a method for manufacturing the sensor device 100 according to the embodiment will be described. FIG. 6 is a flowchart showing the method of manufacturing the sensor device 100. The method for manufacturing the sensor device 100 includes a step S11 of forming the wire bonding pads 16, a step S12 of forming the first resist portion 20, a step S13 of forming the second resist portion 30, a step S14 of forming the third resist portions 40, a step S15 of mounting the semiconductor sensor element 10, and a step S16 of forming the resin layer 53. The method for manufacturing the sensor device 100 may include any other step(s). In the method for manufacturing the sensor device 100, an order of the steps may be changed, or steps may be performed simultaneously.

In the method for manufacturing the sensor device 100, the step S11 of forming the wire bonding pads 16 is performed. In the step S11, the wire bonding pads 16 are formed in the first regions 14 and 15 in the substrate 11. In the step S11, the wire bonding pads 16 and wirings 18 are formed on the substrate 11. As described above, each of the first regions 14 and 15 is a region outside the sensor-element mounted portion 12.

In the method for manufacturing the sensor device 100, the step S12 of forming the first resist portion 20 is performed. In the step S12, the first resist portion 20 is formed between the wire bonding pads 16 and the sensor-element mounted portion 12 so as to surround the sensor-element mounted portion 12 in a plan view. In the step S12, a resist film is formed at a predetermined position to form the first resist portion 20.

In the method for manufacturing the sensor device 100, the step S13 of forming the second resist portion 30 is performed. In the step S13, the second resist portion 30 is formed so as to surround the first resist portion 20 such that the first regions 14 and 15 are interposed between the first resist portion 20 and the second resist portion 30 in a plan view. In the step S13, a resist film is formed at a predetermined position to form the second resist portion 30.

In the method for manufacturing the sensor device 100, the step S14 of forming the third resist portions 40 is performed. In the step S14, each third resist portion 40 extending from the first resist portion 20 toward the second resist portion 30 in a plan view is formed. In the step S14, a resist film is formed at a predetermined position to form each third resist portion 40. In the method for manufacturing the sensor device 100, steps S12 to S14 may be performed simultaneously.

In the method for manufacturing the sensor device 100, the step S15 of mounting the semiconductor sensor device 10 is performed. In the step S15, the semiconductor sensor chip 10 is mounted at the sensor-element mounted portion 12. For example, in the step S15, an adhesive resin is infused onto the sensor-element mounted portion 12 that is surrounded by the first resist portion 20. In the step S15, the semiconductor sensor chip 10 is bonded to the sensor-element mounted portion 12 with the adhesive resin infused onto the sensor-element mounted portion 12.

In the method for manufacturing the sensor device 100, the step S16 of forming the resin layer 53 is performed. In the step S16, as described above, the needle 51 is disposed above each third resist portion 40, and the resin 52 is infused from the needle 51. In the step S16, the resin 52 flows onto the first regions 14 and 15 and the wire bonding pads 16, and then the resin 52 is cured to form the resin layer 53.

In such a method for manufacturing the sensor device 100, the resin 52 can be infused onto each third resist portion 40, and as a result, the resin 52 can be spread along the third resist portion 40. The resin 52 on the third resist portion 40 flows onto the first regions 14 and 15. The resin 52 on the third resist portion 40 flows onto the second resist portion 30 and the third resist portion 40. The resin 52 on the second resist portion 30 and the third resist portion 40 flows onto the first regions 14 and 15. With this approach, in the sensor device 100, the resin 52 can be sufficiently spread. In the sensor device 100, insufficient spreading of the resin can be remedied.

### Sensor Device According to Second Embodiment

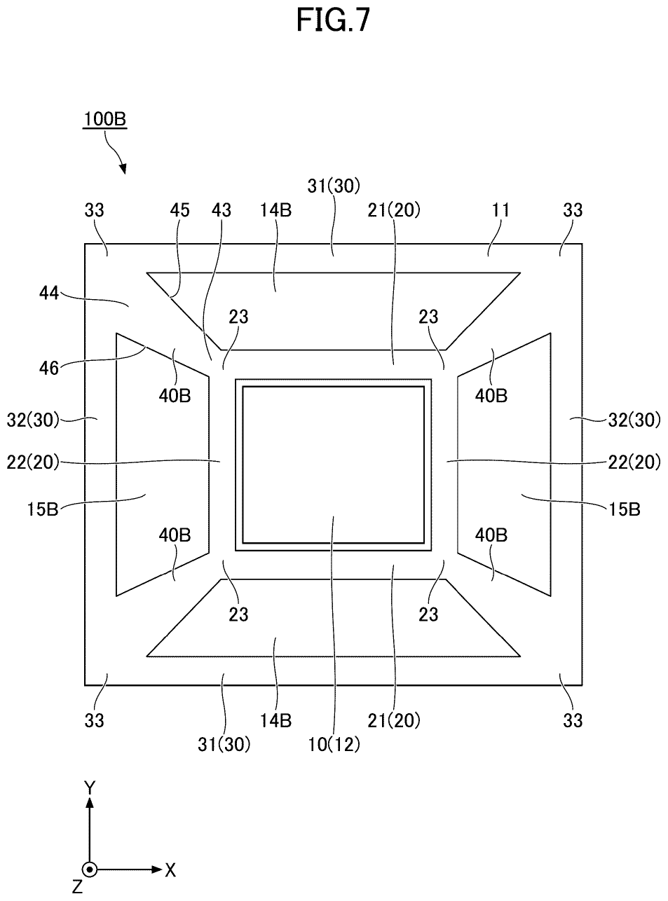

Hereinafter, a sensor device 100B according to a second embodiment will be described with reference to FIG. 7. FIG. 7 is a plan view of the sensor device 100B according to the second embodiment. The sensor device 100B according to the second embodiment shown in FIG. 7 differs from the sensor device 100 according to the first embodiment in that a third resist portion 40B having a different shape from the third resist portion 40 is provided instead of the third resist portion 40. In the sensor device 100B, first regions 14B and 15B having shapes that are each different from that of a corresponding region among the first regions 14 and 15 in the sensor device 100 are formed. In the description of the sensor device 100B according to the second embodiment, the same description as provided in the sensor device 100 according to the first embodiment will be omitted.

### [First Region]

The first regions 14B and 15B are formed to have a trapezoidal shape in a plan view. First regions 14B making a pair are disposed on both sides of the first resist portion 20 in the Y-axis direction. The first regions 15B are disposed on respective sides of the first resist portion 20 in the X-axis direction. Although not shown in FIG. 7, wire bonding pads 16 are formed in the first regions 14B and 15B.

### [Third Resist Portion]

The sensor device 100B includes third resist portions 40B. Each third resist portion 40B extends from the first resist portion 20 toward the second resist portion 30 in a plan view. The third resist portion 40B couples the first resist portion 20 and the second resist portion 30. An end 43 of the third resist portion 40B that is closer to the first resist portion 20 is connected to the corner 23. An end 44 of the third resist portion 40B that is closer to the second resist portion 30 is connected to the corner 33.

The third resist portion 40B has a predetermined length. A width of the third resist portion 40B varies with respect to the longitudinal direction of the third resist portion 40B. The width of the third resist portion 40B is a width in a direction perpendicular to the longitudinal direction of the third resist portion 40B. The width (first width) of the third resist portion 40B that is closer to the first resist portion 20 is narrower than the width (second width) of the third resist portion 40B that is closer to the second resist portion 30. The end 43 closer to the first resist portion 20 is narrower than the end 44 closer to the second resist portion 30. The width of the end 43 may be, for example, greater than or equal to 50% and less than or equal to 80% the width of the end 44.

Sides 45 and 46 of the third resist portion 40B, opposed to each other in a widthwise direction, are, for example, straight lines. Each of the sides 45 and 46 is inclined with respect to the X-axis direction and the Y-axis direction, in a plan view.

### Operation and Effect of Sensor Device According to Second Embodiment

The sensor device 100B according to the second embodiment has the same operation and effect as described in the sensor device 100 according to the first embodiment. In the sensor device 100B, a portion of the third resist portion 40B that is closer to the first resist portion 20 is narrower than a portion of the third resist portion 40B that is closer to the second resist portion 30.

The sensor device 100B according to the second embodiment can be manufactured by the same method as the method for manufacturing the sensor device 100 according to the first embodiment.

The resin 52 infused onto each third resist portion 40B flows toward the end 43 closer to the first resist portion 20. A greater flow rate of the resin 52 that flows on the third resist portion 40B having a small width is obtained in comparison to a case where the third resist portion 40B has a large width. In the third resist portion 40B, the end 43 is the narrowest portion. The flow rate of the resin 52 flowing on the third resist portion 40B increases as the resin 52 approaches the first resist portion 20. In the sensor device 100B, the resin 52 flowing on the third resist portion 40 easily flows onto the first resist portion 20 during manufacturing of the sensor device. In this arrangement, the resin 52 can be further spread in the sensor device 100B. In the sensor device 100B, insufficient spreading of the resin 52 can be remedied during manufacturing of the sensor device.

### Sensor Device According to Third Embodiment

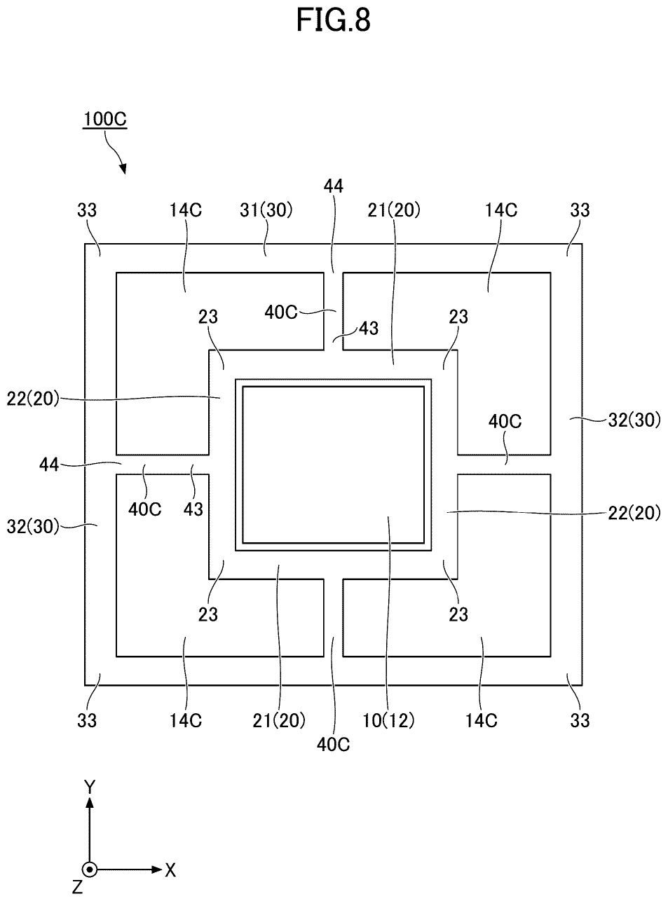

Hereinafter, a sensor device 100C according to a third embodiment will be described with reference to FIG. 8. FIG. 8 is a plan view of the sensor device 100C according to the third embodiment. The sensor device 100C according to the third embodiment shown in FIG. 8 differs from the sensor device 100 according to the first embodiment in that each third resist portion 40C having a different shape from the third resist portion 40 is provided instead of the third resist portion 40. In the sensor device 100C, each first region 14C having a different shape from each of the first regions 14 and 15 in the sensor device 100 is formed. In the description of the sensor device 100C according to the third embodiment, the same description as provided in the sensor device 100 according to the first embodiment will be omitted.

### [Third Resist Portion]

The sensor device 100C includes third resist portions 40C. Each third resist portion 40C extends from the first resist portion 20 toward the second resist portion 30 in a plan view. The third resist portion 40C couples the first resist portion 20 and the second resist portion 30.

Each third resist portion 40C includes a pair of third resist portions 40C extending in the X-axis direction, and includes a pair of third resist portions 40C extending in the Y-axis direction. One end 43 of the third resist portion 40C extending in the X-axis direction is connected to a second piece 22 of the first resist portion 20, and the other end 44 of the third resist portion 40C is connected to a second piece 32 of the second resist portion 30. The end 43 of the third resist portion 40C extending in the X-axis direction is connected to a middle portion in the longitudinal direction of the second piece 22. The end 44 of the third resist portion 40C extending in the X-axis direction is connected to a middle portion in the longitudinal direction of the second piece 32.

One end of the third resist portion 40C extending in the Y-axis direction is connected to a first piece 21 of the first resist portion 20, and the other end 44 of the third resist portion 40C is connected to a first piece 31 of the second resist portion 30. The end 43 of the third resist portion 40C extending in the Y-axis direction is connected to a middle portion in the longitudinal direction of the first piece 21. The end 44 of the third resist portion 40C extending in the Y-axis direction is connected to a middle portion in the longitudinal direction of the first piece 31.

The width of each third resist portion 40C is, for example, uniform. The “width” is a width of the third resist portion 40C in a direction perpendicular to the longitudinal direction of the third resist portion. The end 43 of the third resist portion 40C closer to the first resist portion 20 may be narrower than the end 44 of the third resist portion 40C closer to the second resist portion 30.

### [First Region]

Each first region 14C is formed to have, for example, an L shape in a plan view. The first region 14C includes a portion extending in the X-axis direction, and includes a portion extending in the Y-axis direction. Although not shown in FIG. 8, one or more wire bonding pads 16 are formed in the first region 14C.

### Operation and Effect of Sensor Device According to Third Embodiment

The sensor device 100C according to the third embodiment has the same operation and effect as described in the sensor device 100 according to the first embodiment. In the sensor device 100C, each third resist portion 40C extending in the X-axis direction is connected, at respective ends, to the middle portion of the second piece 22 and the middle portion of the second piece 32. In the sensor device 100C, each third resist portion 40C extending in the Y-axis direction is connected, at respective ends, to the middle portion of the first piece 21 and the middle portion of the first piece 31. With this arrangement, each third resist portion 40C may not be connected to corners 23 and 33. The third resist portion 40C may be connected to respective linear portions of the first resist portion 20 and the second resist portion 30.

In manufacturing the sensor device 100C, the needle 51 is disposed above each third resist portion 40C, and the resin 52 can flow onto the third resist portion. The resin 52 on the third resist portion 40C flows along the third resist portion 40C, and easily flows onto the first resist portion 20. As a result, the resin 52 can be sufficiently spread.

The present disclosure is not limited to the configuration or the like of the sensor device according to the embodiments, and any combinations with the other component(s) may be adopted. Changes and modifications to the embodiments can be also made without departing from the scope of the present disclosure. The combinations, changes, and modifications can be appropriately determined according to an application form.

In the above embodiments, a case where each third resist portion 40 is connected to the first resist portion 20 and the second resist portion 30 is described, but the third resist portion 40 may be connected to only the first resist portion 20, may be connected to only the second resist portion 30, or may not be connected to the first resist portion 20 and the second resist portion 30.

In the above second embodiment, the case where a portion of the third resist portion 40B closer to the first resist portion 20 is narrower than a portion of the third resist portion 40B closer to the second resist portion 30 is described, but the third resist portion 40B is not limited to the above case. A portion of the third resist portion 40B closer to the first resist portion 20 may be wider than a portion of the third resist portion 40B closer to the second resist portion 30.

The shape of the third resist portion 40 is not particularly limited, and may be a shape including a curve, a shape including a circle, a trapezoidal shape, or other shapes. The shape of the third resist portion 40 in a plan view may be an L shape, an I shape, or a Y shape.

In the above embodiments, wire bonding pads 16 are formed in the first regions 14 and 15. However, the wire bonding pads 16 may not be formed in the first regions 14 and 15.

In the present disclosure, a sensor device and a method for manufacturing the sensor device that is capable of remedying insufficient spreading of a resin can be provided.

What is claimed is:

1. A sensor device comprising:
a semiconductor sensor element; and
a substrate on which the semiconductor sensor element is mounted, the substrate including
a sensor-element mounted portion at which the semiconductor sensor element is mounted,
a first resist portion that surrounds the sensor-element mounted portion,
a first region adjacent to the first resist portion, and being covered with a resin layer,
a second resist portion that surrounds the first resist portion, the first region being interposed between the first resist portion and the second resist portion, and
at least one third resist portion extending from the first resist portion toward the second resist portion.

2. The sensor device according to claim 1, wherein the third resist portion connects the first resist portion and the second resist portion.

3. The sensor device according to claim 1, wherein a portion of the third resist portion closer to the first resist portion is narrower than a portion of the third resist portion closer to the second resist portion.

4. The sensor device according to claim 1, wherein the first resist portion has a rectangular shape in a plan view, the first resist portion including
two first pieces facing each other in a first direction, and extending in a second direction, and
two second pieces facing each other in the second direction, and extending in the first direction, and
wherein the at least one third resist portion includes third resist portions each of which is connected to a corner where a corresponding first piece among the two first pieces and a corresponding second piece among the two second pieces intersect with each other.

5. The sensor device according to claim 4, wherein each of the third resist portions includes
a first portion extending from the corner in the second direction, and being connected to the second resist portion, and
a second portion connected to the first portion, and extending in the first direction.

6. A method for manufacturing a sensor device by mounting a semiconductor sensor element at a sensor-element mounted portion in a substrate, the method comprising:
forming a first resist portion to surround the sensor-element mounted portion;
forming a second resist portion to surround the first resist portion such that a first region is interposed between the first resist portion and the second resist portion;
forming at least one third resist portion that extends from the first resist portion toward the second resist portion;
disposing a resin infusion unit above the third resist portion and infusing a resin from the resin infusion unit; and
forming a resin layer that covers the first region as a result of infusing the resin.
